(19) United States
(12) Patent Application Publication
(10) Pub. No.: US 2021/0305016 A1
(43) Pub. Date: Sep. 30, 2021

(54) SPECIFIC TYPE ION SOURCE AND PLASMA FILM FORMING APPARATUS

(71) Applicants: National University Corporation Kyoto Institute of Technology, Kyoto-shi, Kyoto (JP); Tokyo Electron Limited, Tokyo (JP)

(72) Inventor: Haruhiko Himura, Kyoto-shi, Kyoto (JP)

(21) Appl. No.: 17/251,362

(22) PCT Filed: Nov. 7, 2018
(86) PCT No.: PCT/JP2018/041365

§ 371 Date: Dec. 11, 2020

(30) Foreign Application Priority Data
Jun. 14, 2018 (JP) 2018-113593

(51) Int. Cl. H01J 37/32; C23C 16/40; C23C 16/50; C23C 16/455

(52) U.S. Cl. CPC H01J 37/32082; H01J 37/3244; C23C 16/407; H01J 2237/332; C23C 16/45536; H01J 2237/04732; C23C 16/50

(57) ABSTRACT

A specific type ion source 10 includes a chamber 11; a source gas supply 12 configured to supply an O₂ gas into the chamber 11; a plasma forming device 13 configured to form plasma within the chamber 11 by applying a high frequency power to the O₂ gas supplied into the chamber 11; an accelerator 14 configured to extract ions of an O element included in the plasma formed within the chamber 11 to an outside of the chamber 11, and configured to accelerate the extracted ions in a direction indicated by an arrow AR14; and a sorting device 15 configured to sort out a specific type ion O⁻ from the ions accelerated by the accelerator 14 and configured to output the sorted specific type ion in a direction indicated by an arrow AR12.

### TECHNICAL FIELD

The various aspects and embodiments described herein pertain generally to a specific type ion source and a plasma film forming apparatus.

### BACKGROUND

Along with the development of IoT technology, a mobile device is required to be scaled down and high-functionalized. Various kinds of devices such as a sensor, an actuator, or other circuit elements mounted to the mobile device are getting miniaturized and complicated as the mobile device is sized down and high-functionalized. As these various kinds of devices are miniaturized and complicated, a manufacturing method for a nanostructure including a quantum dot or a thin film manufacturing method are attracting attention as an important elemental technology for manufacturing these various kinds of devices.

As a manufacturing method for the quantum dot, there are mainly employed a method of forming the quantum dot with a bulk semiconductor material or a method of self-forming the quantum dot by using a stress generated when a crystal grows on a surface of a semiconductor substrate. Neither of these manufacturing methods, however, meets requirements for quality and uniformity of the quantum dot.

Further, a minimum processing dimension required for a current highest-tech semiconductor device is about 7 nm. To meet this requirement, a film thickness control on a nanoscale is required to be conducted in the thin film forming method. In this case, in a film forming method such as a sputtering method or a CVD (Chemical Vapor Deposition) method, it is difficult to satisfy the aforementioned requirement sufficiently. Thus, as the thin film forming method, there is employed a method such as an ALD (Atomic Layer Deposition) method in which a film thickness can be controlled on an atomic layer level. As such an ALD method, there is known a PEALD (Plasma-Enhanced Atomic Layer Deposition) method which is conducted by forming plasma including ions or radicals of an atom to be deposited. In this PEALD method, however, it is difficult to control a behavior of the ions, the radicals or electrons included in the formed plasma, particularly, energy of the ions. As a result, there is a concern that a damage may be inflicted on surfaces of various kinds of devices manufactured by the PEALD method, resulting in degradation of performance and reliability of the devices. Furthermore, since energy for forming the plasma is continuously inputted into a plasma generation chamber from the outside, the plasma is not thermally alleviated. For the reason, temporal or spatial fluctuations exist in the energy and number density of the plasma. Because of these plasma fluctuations, a film thickness of a thin film to be formed is difficult to uniform to a nanometer order. Further, the degree of these fluctuations may differ for individual plasma generating apparatuses, depending on a plasma generation method, a distance between the plasma and a metal or an insulator in contact with the plasma, such as an inner wall of a plasma generation vessel or an embedded electrode, and a difference in a transport coefficient within the plasma generation vessel. Moreover, light such as an ultraviolet ray generated from the plasma is one of factors that cause a damage on a surface of the film. So far, there is known no general method capable of carrying out micro-processing on a nanoscale by using plasma without depending on the plasma generating apparatus.

Thus, in the nanostructure manufacturing method or the thin film forming method, to improve quality of the nanostructure or the thin film and achieve uniformity thereof, it is required to selectively extract specific type ions or radicals having high reactivity, that is, high chemical activity, allowing them to contribute to the formation of the nanostructure or the thin film. In this regard, there is proposed a technique of extracting, for example, oxygen anions (O⁻) having high chemical activity and using these extracted oxygen anions (see, for example, Patent Document 1). In the disclosure of the Patent document 1, a plasma gun is used as an ion source of the oxygen anions.

### PRIOR ART DOCUMENT

Patent Document 1: Japanese Patent Laid-open Publication No. 2017-025407

### DISCLOSURE OF THE INVENTION

### Problems to be Solved by the Invention

In the aforementioned nanostructure manufacturing method or thin film manufacturing method, however, it is required to improve purity of the extracted specific type ions having the high chemical activity in order to improve the quality of the nanostructure or the thin film and achieve the uniformity thereof. Further, in the formation of the nano structure or the thin film, only the specific type ions need to contribute to the formation without allowing other kinds of ions to contribute. This is also required in a process in which only specific type radicals are allowed to contribute.

In view of the foregoing, exemplary embodiments provide a specific type ion source and a plasma film forming apparatus capable of acquiring specific type ions or radicals from a plasma source with high purity.

### Means for Solving the Problems

In an exemplary embodiment, a specific type ion source includes a chamber; a first source gas supply configured to supply a first source gas into the chamber; a plasma forming device configured to form plasma within the chamber by applying a high frequency power to the first source gas supplied into the chamber; an accelerator configured to extract ions of an element of the first source gas included in the plasma formed within the chamber to an outside of the chamber, and configured to accelerate the extracted ions in a preset first direction; and a sorting device configured to sort out a specific type ion from the ions accelerated by the accelerator and configured to output the sorted specific type ion in a predetermined second direction.

In another exemplary embodiment, a plasma film forming apparatus includes a specific type ion source comprising a chamber; a first source gas supply configured to supply a first source gas into the chamber; a plasma forming device configured to form plasma within the chamber by applying a high frequency power to the first source gas supplied into the chamber; an accelerator configured to extract ions of an element of the first source gas included in the plasma formed within the chamber to an outside of the chamber, and configured to accelerate the extracted ions in a preset first direction; and a sorting device configured to sort out a specific type ion from the ions accelerated by the accelerator and configured to output the sorted specific type ion in a predetermined second direction; a second source gas supply configured to supply a second source gas; and a reactor configured to allow the specific type ion supplied by the specific type ion source to react with the second source gas.

### Effect of the Invention

According to the exemplary embodiments, the accelerator extracts the ions of the element of the first source gas included in the plasma formed within the chamber, and accelerates the extracted ions in the preset first direction. Then, the sorting device sorts out the specific type ion from the ions accelerated by the accelerator and outputs the sorted specific type ion in the preset second direction. Accordingly, the specific type ion can be obtained with high purity.

### BRIEF DESCRIPTION OF THE DRAWINGS

FIG. 1 is a schematic diagram illustrating a plasma film forming apparatus according to a first exemplary embodiment of the present disclosure.

FIG. 2 is an exploded perspective view illustrating a part of a specific type ion source according to the first exemplary embodiment.

FIG. 3 is a cross sectional view illustrating a part of the specific type ion source according to the first exemplary embodiment.

FIG. 4A is a schematic perspective view of a first magnet according to the first exemplary embodiment.

FIG. 4B is a schematic plan view illustrating a part of a plasma forming device according to the first exemplary embodiment.

FIG. 5 is a schematic cross sectional view illustrating a part of the specific type ion source according to the first exemplary embodiment.

FIG. 6A is a schematic diagram illustrating a part of the specific type ion source according to the first exemplary embodiment.

FIG. 6B is a schematic diagram illustrating a part of the specific type ion source according to the first exemplary embodiment, seen from a direction different from in FIG. 6A.

FIG. 7 is a cross sectional view illustrating a part of a specific type ion source according to a comparative example.

FIG. 8A is a diagram showing a simulation result for a magnetic field distribution according to the first exemplary embodiment.

FIG. 8B is a diagram showing a simulation result for a magnetic field distribution according to the comparative example.

FIG. 9A is a chart showing plasma ignition pressures according to the first exemplary embodiment and the comparative example.

FIG. 9B is a chart showing electron temperatures of plasma according to the first exemplary embodiment and the comparative example.

FIG. 10 is a diagram for describing an operation of the plasma film forming apparatus according to the first exemplary embodiment.

FIG. 11 is a schematic diagram illustrating a plasma film forming apparatus according to a second exemplary embodiment.

FIG. 12A is a time chart for describing the contents of a control over a RF power supply and a supply valve by a controller according to the second exemplary embodiment.

FIG. 12B is a diagram showing a pressure variation at a downstream of a plasma forming device according to the second exemplary embodiment.

FIG. 13 is a diagram illustrating an emission spectrum of plasma formed within a chamber according to the second exemplary embodiment.

FIG. 14A is a schematic plan view illustrating a part of a plasma forming device according to a modification example.

FIG. 14B is a schematic plan view illustrating a part of a plasma forming device according to a modification example.

FIG. 15 is a chart showing dependency of a pressure within a chamber of the plasma forming device according to the modification example upon a central magnetic flux density of a first magnet according to a modification example.

FIG. 16A is a schematic perspective view of a first magnet according to a modification example.

FIG. 16B is a schematic plan view illustrating a part of a plasma forming device according to a modification example.

### DETAILED DESCRIPTION

### First Exemplary Embodiment

Hereinafter, a plasma film forming apparatus according to a first exemplary embodiment will be described in detail with reference to the accompanying drawings. The plasma film forming apparatus according to the present exemplary embodiment is equipped with a specific type ion source configured to receive a first source gas supplied thereto and output a specific type ion; a second source gas supply configured to supply a second source gas; and a reactor configured to allow the specific type ion supplied by the specific type ion source and the second source gas to react with each other. The specific type ion source includes a chamber, a first source gas supply configured to supply the first source gas into the chamber, a plasma forming device, an accelerator, and a sorting device. The plasma forming device forms plasma within the chamber by applying a high frequency power to the first source gas supplied into the chamber. The accelerator extracts ions of an element of the first source gas included in the plasma formed within the chamber to an outside of the chamber, and accelerates the extracted ions in a preset first direction. The sorting device sorts out the specific type ion from the ions accelerated by the accelerator and outputs the specific type ion in a preset second direction. Oxygen, nitrogen, hydrogen, carbon or the like can be used as the specific type ion for a precursor of various kinds of organic metals. The present exemplary embodiment will be described for a case where the specific type ion also serving as a charged particle is an oxygen anion (O⁻) having high chemical reactivity, and the second source gas is DEZn (diethyl zinc). In the field of chemistry, O⁻ is called “oxygen anion radical,” and has the same electron configuration as that of fluorine (F) having high chemical reactivity and features high chemical activity.

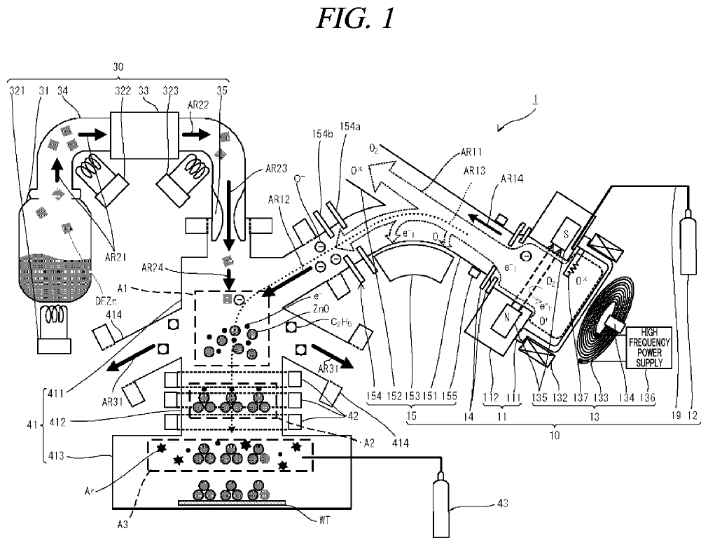

As shown in FIG. 1, a plasma film forming apparatus 1 according to the first exemplary embodiment includes a specific type ion source 10; a source gas supply 30 as a second source gas supply; a reactor 41; an electromagnetic field generator 42; and an Ar gas supply source 43. The specific type ion source 10 is equipped with a chamber 11; a source gas supply 12 as a first source gas supply; a source gas supply pipe 19 which communicates with the chamber 11 and supplies the first source gas into the chamber 11; a plasma forming device 13; an accelerator 14; and a sorting device 15.

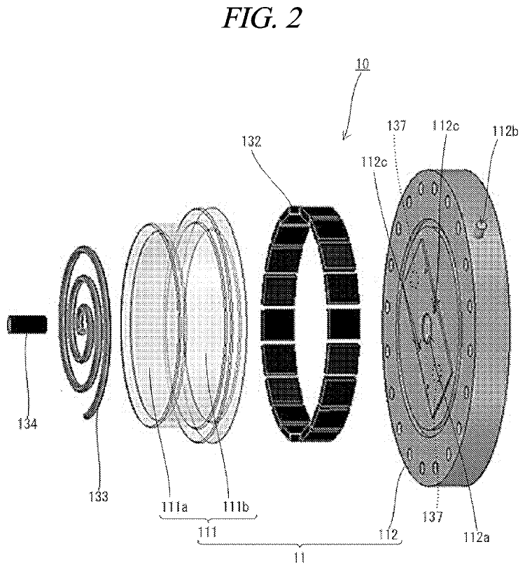

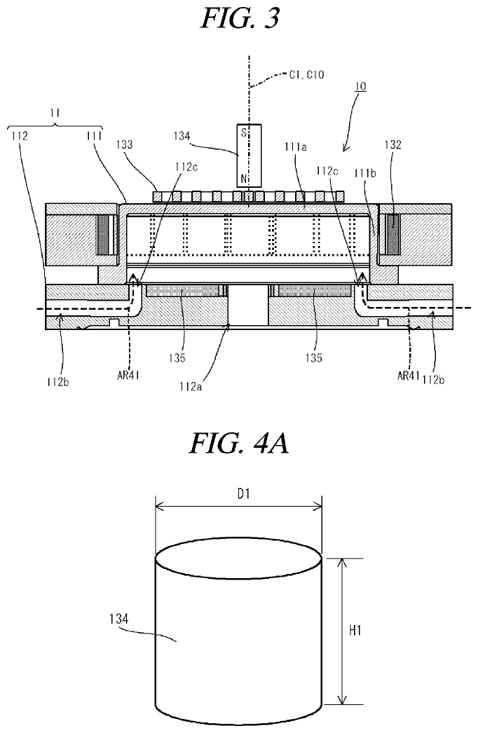

The chamber 11 has, as depicted in FIG. 2, for example, a cylindrical chamber main body 111 and a cover body 112 configured to close an opening portion of the chamber main body 111. The chamber main body 111 is made of, by way of non-limiting example, a dielectric material which transmits a high frequency power. Further, only a portion, which introduces a high frequency power from the outside, of a sidewall of the chamber main body 111 may be made of the dielectric material, while the rest of the sidewall of the chamber main body 111 may be made of a metal. The cover body 112 is provided with a release hole 112a formed through a central portion thereof in a thickness direction. The release hole 112a has a circular shape when viewed from the top, and ions included in plasma formed within the chamber 11 are released to an outside of the chamber 11 through this release hole 112a. Furthermore, the cover body 112 is also provided with openings 112c through which a source gas is discharged to the inside of the chamber main body 111; and an inlet hole 112b communicating with the openings 112c, as illustrated in FIG. 3.

Referring back to FIG. 1, the source gas supply 12 is connected to the inlet hole 112b of the chamber 11 via the source gas supply pipe 19. The source gas supply 12 supplies an oxygen (O₂) gas as the first source gas into the chamber 11 through the source gas supply pipe 19, and the inlet hole 112b and the openings 112c of the chamber 11, as indicated by an arrow AR41 in FIG. 3.

The plasma forming device 13 forms plasma PLM within the chamber 11 by applying a high frequency current to the O₂ gas supplied into the chamber 11. The plasma forming device 13 includes a coil 133 having a spiral shape when viewed from the top; a first magnet 134; a second magnet 132; third magnets 135; and a high frequency power supply 136 configured to supply a high frequency AC current to the coil 133. The coil 133 is disposed at a position at an outside of the chamber main body 11, facing a bottom wall 111a of the chamber main body 111, as illustrated in FIG. 3. Further, the coil 133 receives the high frequency current from a high frequency current source, and applies the high frequency current to the O₂ gas existing within the chamber main body 111. The high frequency power supply 136 supplies the high frequency AC current having a frequency of, e.g., 13.56 MHz to the coil 133.

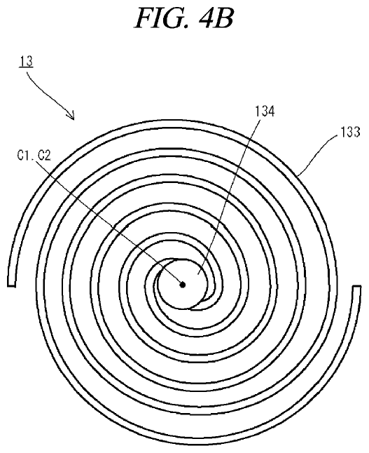

The first magnet 134 is a permanent magnet, and is disposed at an opposite side from the bottom wall 111a of the chamber main body 111 with respect to the coil 133 therebetween. The first magnet 134 is disposed such that a side thereof near the chamber 11 serves an N pole, for example. The first magnet 134 has a circular column shape having a diameter D1 and a height H1, as illustrated in FIG. 4A, for example. The first magnet 134 may be made of, by way of non-limiting example, a NdFeB-based magnetic material. Further, the diameter D1 is set to be, e.g., 20 mm, and the height H1 is set to be, e.g., 10 mm or 20 mm. As illustrated in FIG. 4B, the first magnet 134 is placed such that a central axis C2 of the first magnet 134 substantially coincides with a central axis C1 of the coil 133 when viewed from the top. The second magnet 132 is disposed at an outside of the chamber main body 111, surrounding the sidewall 111b of the chamber main body 111. The third magnets 135 are permanent magnets, and are buried in portions of the cover body 112 of the chamber 11 surrounding the release hole 112a.

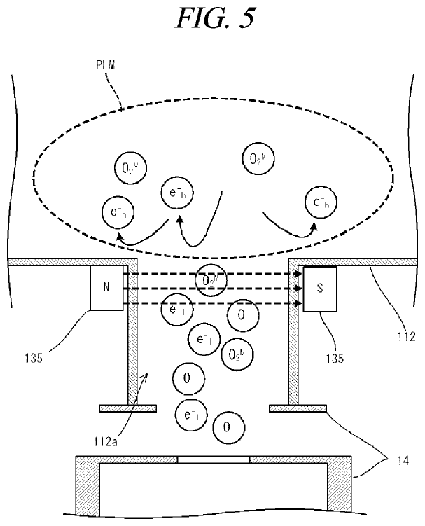

The third magnet 135 serves as a so-called magnetic filter which transmits only low-velocity electrons e⁻ₗ to the outside of the chamber 11 selectively among high-velocity electrons e⁻ₕ having relatively high energy and the low-velocity electrons e⁻ₗ having relatively low energy included in the plasma PLM, as shown in FIG. 5. Accordingly, the low-velocity electrons e⁻ₗ, O₂ molecules O₂^{M} and O⁻ ions O⁻ are released to the outside of the chamber 11 from the release hole 112a of the cover body 112 as major components, and the high-velocity electrons are substantially captured within the chamber 11.

Referring back to FIG. 1, the plasma forming device 13 has a filament 137 serving as an electron supply which supplies electrons into the chamber 11. The filament 137 is desirably made of a material having durability, for example, tungsten or tantalum. The plasma forming device 13 heats the filament 137 by flowing an electric current thereto, thus allowing thermal electrons to be emitted into the chamber 11 from the filament 137. Accordingly, a plasma discharge inception power and a gas pressure within the chamber 11 can be reduced.

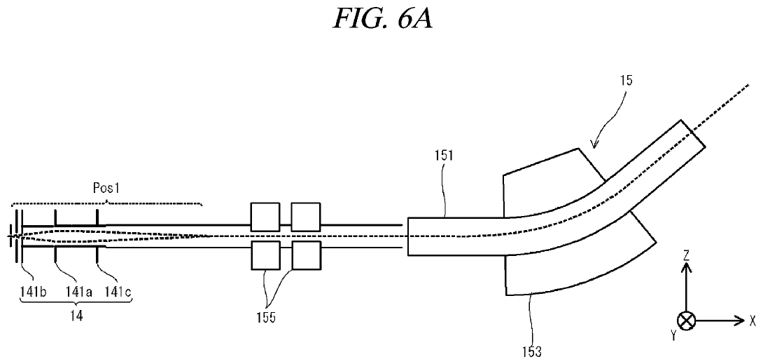

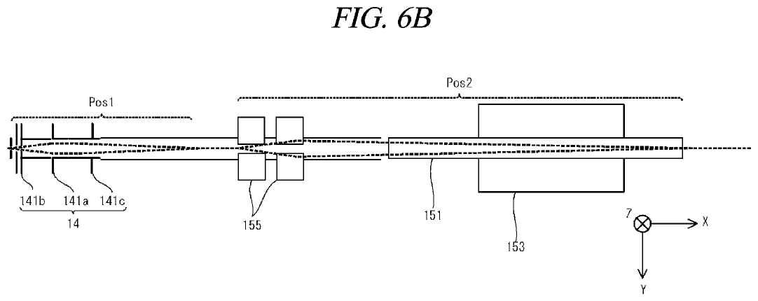

The accelerator 14 extracts, to the outside of the chamber 11, ions of an element of the O₂ gas included in the plasma PML formed within the chamber 11, for example, charged particles of O⁺ ions or the O⁻ ions having positive or negative polarity depending on whether a potential difference is positive or negative; and O radicals which are electrically neutral. The accelerator 14 is an Einzel lens and accelerates the extracted ions in a preset first direction, for example, in a direction indicated by an arrow AR14. As depicted in FIG. 5, by using an electromagnetic field, the accelerator 14 concentrates the ions extracted to the outside of the chamber 11. The accelerator 14 is an electrostatic lens having a central electrode 141a; and electrodes 141b and 141c disposed at the front and the rear in the direction indicated by the arrow AR14, as shown in FIG. 6A and FIG. 6B. FIG. 6A is a ZX plan view and FIG. 6B is a XY plan view. The accelerator 14 concentrates the ions by the electromagnetic field formed by the electrodes 141a, 141b and 141c at a position Pos1 shown in FIG. 6A and FIG. 6B. Furthermore, the accelerator 14 concentrates a beam of the aforementioned charged particles while accelerating or decelerating it by generating a potential difference between the electrodes 141a, 141b and 141c.

Referring back to FIG. 1, the sorting device 15 sorts out specific type ions from the ions accelerated by the accelerator 14 and outputs the sorted specific type ions in a preset second direction, that is, in a direction indicated by an arrow AR12. The sorting device 15 includes a main pipe 151, a branch pipe 152, a magnetic field generator 153, an accelerating/decelerating unit 154, and a quadruple magnet 155. One end of the main pipe 151 is connected to the chamber 11, and the other end thereof is connected to the reactor 41. The main pipe 151 is bent at a portion where the magnetic field generator 153 is placed. A flying velocity of the O⁻ ions accelerated by the accelerator 14 and an intensity of a magnetic field generated by the magnetic field generator 153 are set based on a curvature of the main pipe 151. By bending the main body 151 in this way, light such as a ultraviolet ray emitted from the plasma forming device 13 can be suppressed from reaching the reactor 41 directly.

The quadruple magnet 155 generates, at a position Post of FIG. 6B, the magnetic field and concentrates the beam of the aforementioned charged particles.

The magnetic field generator 153 is an electromagnet and generates the magnetic field of a third direction perpendicular to the paper plane of FIG. 1. The branch pipe 152 extends in a direction indicated by an arrow AR14. The accelerating/decelerating unit 154 has two electrodes 154a and 154b arranged in an extension direction of the main pipe 151. By generating a potential difference between the two electrodes 154a and 154b and the accelerator 14, the accelerating/decelerating unit 154 accelerates or decelerates the O⁻ ions.

In the sorting device 15, since the O₂ molecules O₂ and the O radicals O* emitted into the main pipe 151 from the chamber 11 are hardly affected by the magnetic field generated by the magnetic field generator 153, they are released toward the branch pipe 152, as indicated by an arrow AR11 of FIG. 1. Further, a flying direction of most of the O⁺ ions and the low-velocity electrons e⁻ₗ emitted into the main pipe 151 from the chamber 11 is largely bent by the magnetic field generated by the magnetic field generator 153, and most of the O⁺ ions and the low-velocity electrons e⁻ₗ are absorbed into a pipe wall of the main pipe 151. Accordingly, only the O⁻ ions are guided into the reactor 41 after being accelerated or decelerated by the accelerating/decelerating unit 154, as indicated by an arrow AR13 in FIG. 1. That is, the sorting device 15 sorts out only the O⁻ ions among the ions and the low-velocity electrons emitted from the chamber 11, and guides the sorted O⁻ ions into the reactor 41.

In the specific type ion source 10 according to the present exemplary embodiment, if the high frequency power is applied from the coil 133 to the O₂ gas introduced into the chamber 11, the O₂ molecules, the electrons e⁻ₗ and e⁻ₕ, the O⁺ ions, the O radicals O* and the O⁻ ions are generated within the chamber 11. Then, the O₂ molecules, the low-velocity electrons e⁻ₗ, the O⁺ ions, the O radicals O* and the O⁻ ions are emitted to the outside of the chamber 11 by the magnetic field formed by the first magnet 134, the second magnet 132 and the third magnets 135. Here, the first magnet 134 serves to improve generation efficiency of the O⁻ ions. At this time, a considerable amount of the high-velocity electrons e⁻ₕ are adsorbed into an inner wall of the chamber 11 and disappear. The sorting device 15 sorts out only the O⁻ ions among the O₂ molecules, the low-velocity electrons e⁻ₗ, the O⁺ ions, the O radicals O* and the O⁻ ions, and introduces the sorted O⁻ ions into the reactor 41.

The source gas supply 30 includes a storage 31 configured to store therein DEZn in a liquid state; a supply pipe 34 for supplying vaporized DEZn into the reactor 41 as a second source gas; a flow rate control valve 33 configured to adjust a flow rate of the DEZn supplied into the reactor 41; and a nozzle 35. Further, the source gas supply 30 is equipped with a heater 321 configured to heat the storage 31; and heaters 322 and 323 configured to heat the supply pipe 34. The heater 321 heats the DEZn stored in the storage 31 to a temperature of, e.g., 60° C. Accordingly, the vaporized DEZn is supplied to the flow rate control valve 33 from the storage 31 (see an arrow AR21 of FIG. 1). The heater 322 heats a portion of the supply pipe 34 at an upstream of the flow rate control valve 33 to, e.g., 70° C. The DEZn flown out from the flow rate control valve 33 is supplied to the nozzle 35 (see an arrow AR22 of FIG. 1). The heater 323 heats a portion of the supply pipe 34 at a downstream of the flow rate control valve 33 to, e.g., 80° C. The nozzle 35 is provided at a downstream end of the supply pipe 34 and introduces the vaporized DEZn into a specific position within the reactor 41 at a flow velocity of, e.g., Mach 5 (see arrows AR23 and AR24 of FIG. 1).

The reactor 41 is configured to allow the O⁻ ions supplied by the specific type ion source 10 and the vaporized DEZn to react with each other. The reactor 41 is equipped with a reaction chamber 411 in which the O⁻ ions and the vaporized DEZn meet and react; a trapping/growth chamber 412; and a growth chamber 413. A substrate WT is disposed in the growth chamber 413. The electromagnetic field generator 42 is disposed at an outside of the reactor 41, surrounding the trapping/growth chamber 412, and generates an electromagnetic field within the trapping/growth chamber 412. The Ar gas supply source 43 supplies an Ar gas into the growth chamber 413 of the reactor 41.

Here, in a zone A1 within the reaction chamber 411 where the O⁻ ions and the vaporized DEZn meet, a chemical reaction represented by the following expression (1) takes place, so that ZnO⁻ ions and ethane (C₂H₅) are generated.

DEZn+O⁻→ZnO⁻+C₂H₅ Expression (1)

The C₂H₅ generated in the zone A1 is exhausted to the outside of the reactor 411 through an exhaust line 414 communicating with the reactor 411, as indicated by an arrow AR31 of FIG. 1. Further, the ZnO⁻ ions generated in the zone A1 move into the trapping/growth chamber 412 (in FIG. 1, the ZnO⁻ ions and ZnO are indicated by the same notation). The electromagnetic field generator 42 generates the electromagnetic field within the trapping/growth chamber 412, thus allowing the ZnO⁻ ions, which are ions of ZnO as a compound including an element O and an element Zn, to be trapped into a zone A2 within the trapping/growth chamber 412. Accordingly, a cluster of the ZnO⁻ ions is formed in the zone A2. Then, by removing a potential barrier formed in the electromagnetic field generator 42 after a lapse of a predetermined time, the cluster of the ZnO⁻ ions generated in the zone A2 move into the growth chamber 413.

Here, in a zone A3 within the growth chamber 413, as the Ar gas is supplied from the Ar gas supply source 43, a chemical reaction represented by the following expression (2) takes place.

ZnO⁻+Ar→ZnO+Ar+e⁻ Expression (2)

Accordingly, a cluster of the ZnO is allowed to grow on the substrate WT. Here, though the cluster of the ZnO is allowed to grow on the substrate WT, it may be possible to collect fine particles (quantum dots are possible) of the ZnO by providing a mechanism (not shown) configured to exhaust the cluster of the ZnO⁻ ions within the zone A2 or the cluster of the ZnO within the zone A3 to the outside.

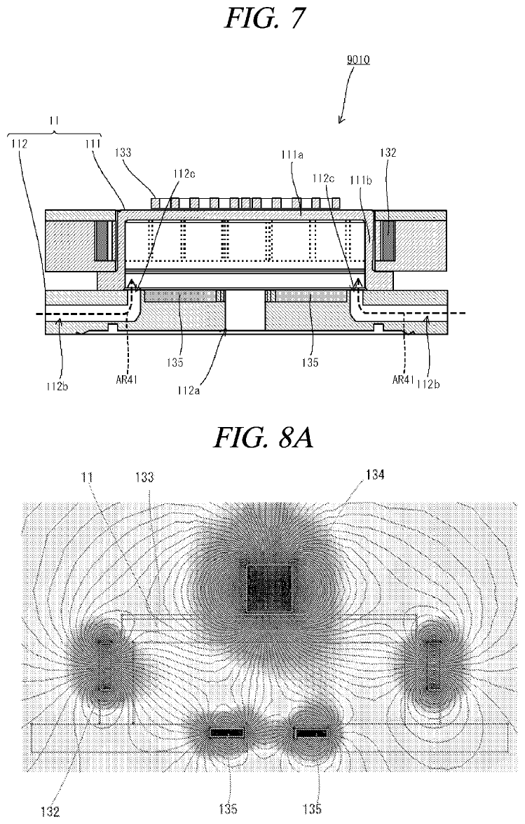

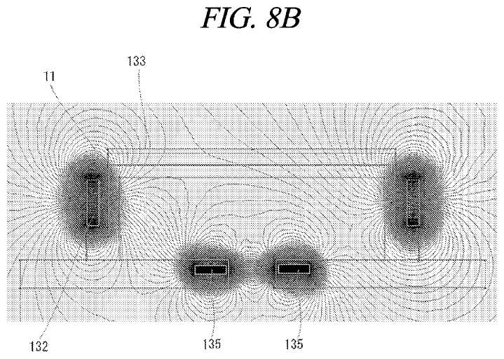

Now, characteristics of the specific type ion source 10 according to the present exemplary embodiment will be described in comparison with a comparative example. Here, as the comparative example, a specific type ion source 9010 shown in FIG. 7 is used. In FIG. 7, parts identical to those of the first exemplary embodiment will be assigned the same reference numerals as used in FIG. 3. This specific type ion source 9010 is different from the specific type ion source 10 of the first exemplary embodiment in that it does not have the first magnet 134. FIG. 8A and FIG. 8B show results of simulations of a magnetic field distribution in the chamber 11 conducted for the specific type ion source 10 of the present exemplary embodiment and the specific type ion source 9010 of the comparative example, respectively. As shown in FIG. 8A and FIG. 8B, a magnetic field intensity of the specific type ion source 10 of the present exemplary embodiment within the chamber 11 is in overall higher than a magnetic field intensity of the specific type ion source 9010 of the comparative example. Particularly, since the magnetic field intensity near the coil 133 is enhanced and a space within the chamber 11 is thus surrounded by a ferromagnetic field, O⁻ is efficiently generated when plasma of a certain gas escapes between the third magnets 135. According to the present disclosure, it is first found out that the generation efficiency of the O⁻ ions can be improved by providing the first magnet 134, that is, by increasing the magnetic field intensity at the coil 133 side and surrounding the space within the chamber 11 with the ferromagnetic field. To enhance the magnetic field intensity at the coil 133 side, a permanent magnet or an electromagnet may be used as the first magnet 134.

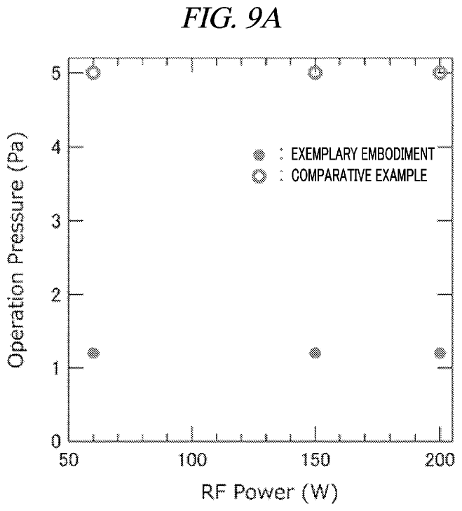

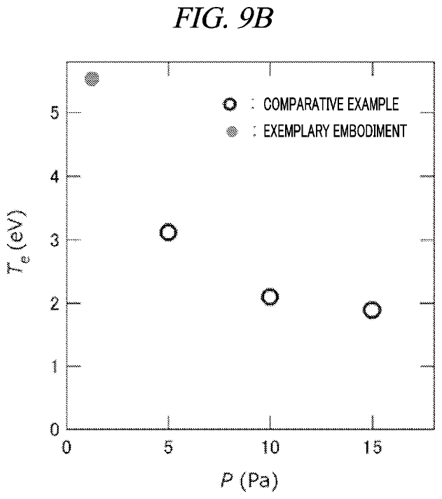

FIG. 9A shows a relationship between a pressure within the chamber 11 required for the generation of the ions and a power supplied to the coil 133 from the high frequency power supply for each of the specific type ion source 10 according to the present exemplary embodiment and the specific type ion source 9010 according to the comparative example. As can be seen from FIG. 9A, the specific type ion source 10 of the present exemplary embodiment is capable of generating the ions even if the pressure within the chamber 11 is low, as compared to the specific type ion source 9010 of the comparative example. As can be seen from this result, it is proved that the specific type ion source 10 according to the present exemplary embodiment is capable of reducing an amount of the O₂ gas introduced into the chamber 11, as compared to the specific type ion source 9010 of the comparative example. Since the specific type ion source 10 of the present exemplary embodiment is capable of generating the ions with high efficiency, the amount of the O2( ) gas used in this specific type ion source 10 becomes smaller than an amount of the O₂ gas used in the specific type ion source 9010 of the comparative example. Thus, running cost can be reduced, and the ions can be generated stably.

Further, FIG. 9B shows a relationship between an electron temperature of the generated O⁻ ions and a pressure within the chamber 11 for each of the specific type ion source 10 according to the present exemplary embodiment and the specific type ion source 9010 according to the comparative example. As can be seen from FIG. 9B, according to the specific type ion source 10 of the present exemplary embodiment, the electron temperature of the generated O⁻ ions is found to be high, that is, energy of the generated O⁻ ions is found to be high even if the pressure within the chamber 11 is low, as compared to the specific type ion source 9010 of the comparative example. As can be seen from this result, the specific type ion source 10 of the present exemplary embodiment is capable of generating the high-energy O⁻ ions having high reactivity while reducing the amount of the O₂ gas introduced into the chamber 11, as compared to the specific type ion source 9010 of the comparative example.

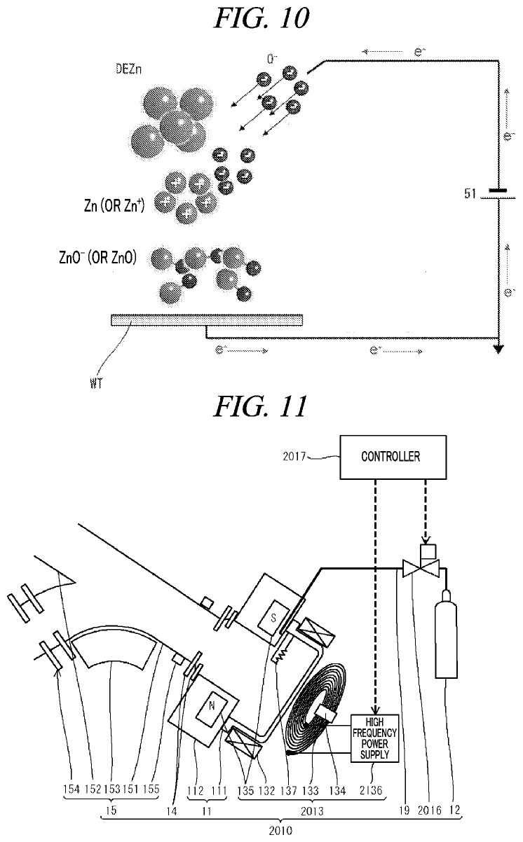

Now, an operation of the plasma film forming apparatus 1 according to the present exemplary embodiment will be explained. As shown in FIG. 10, in the zone A1 of the reaction chamber 411 of the reactor 41, the DEZn in the gas state supplied into the zone A1 is oxidized by a strong oxidizing power of the O⁻ ions, so that Zn or Zn⁺ is generated. The O⁻ ion reacts with the Zn or Zn⁺, so that ZnO⁻ or ZnO is produced. Here, in the plasma film forming apparatus 1 according to the present exemplary embodiment, a bias is applied by a bias application unit 51 such that the substrate WT is of a positive potential with respect to the accelerator 14 of the specific type ion source. Accordingly, accumulation of negative charges in the substrate WT, that is, a charge-up is suppressed. Thus, a cluster generated by agglomerating the ZnO⁻ or ZnO in the trapping/growth chamber 412 can be grown into a film on the substrate WT stably. Further, a size and a density of the cluster of the ZnO⁻ ions grown on the substrate WT can be varied by changing a magnitude of an electric field and a magnetic field generated within the trapping/growth chamber 412 by the electromagnetic field generator 42. Furthermore, a size of the cluster of the ZnO grown on the substrate WT can be varied by adjusting a timing for removing the potential barrier generated within the trapping/growth chamber 412 by the electromagnetic field generator 42. When the cluster is extracted to the outside as fine particles, a particle size can be controlled.

As stated above, according to the specific type ion source 10 of the present exemplary embodiment, the accelerator 14 extracts the ions of the element of the O₂ gas included in the plasma PLM formed within the chamber 11 to the outside of the chamber 11, and accelerates the extracted ions in the direction indicated by the arrow AR14 of FIG. 1. Then, the sorting device 15 sorts out the O⁻ ions among the ions accelerated by the accelerator 14 and outputs the sorted O⁻ ions in the direction indicated by the arrow AR12 of FIG. 1. Accordingly, the O⁻ ions can be obtained with high purity. Thus, quality and uniformity of the ZnO cluster formed on the substrate WT can be improved.

Furthermore, in the specific type ion source 10 according to the present exemplary embodiment, the electric field of the accelerator 14 and the magnetic field of the sorting device 15 change a deflection trajectory of the O⁻ ions introduced into the reactor 41, and the accelerating/decelerating unit 154, which decelerates the ions, performs a final adjustment of the deflection trajectory. By changing a reaching position of the O⁻ ions, a position of the zone in which the DEZn and the O⁻ ions react with each other can be changed. Therefore, a deposition position of the ZnO cluster on the substrate WT can be selected.

### Second Exemplary Embodiment

A plasma film forming apparatus according to the second exemplary embodiment is different from the plasma film forming apparatus of the first exemplary embodiment in that a specific type ion source receives a first source gas supplied into a chamber thereof instantly and outputs specific type ions. The plasma film forming apparatus having this specific type ion source can improve the degree of freedom in setting a vacuum level of an apparatus at a downstream of the specific type ion source, including a reactor. Thus, by increasing the vacuum level, for example, it is possible to carry out easy control over a behavior of the specific type ions outputted from the specific type ion source.

By way of example, as shown in FIG. 11, a specific type ion source 2010 according to the second exemplary embodiment includes a chamber 11, a source gas supply 12, a source gas supply pipe 19, a plasma forming device 2013, an accelerator 14, a sorting device 15, an electromagnetic valve 2016, and a controller 2017. Further, in FIG. 11, the parts identical to those of the first exemplary embodiment are assigned the same reference numerals as used in FIG. 1. The plasma forming device 2013 includes, the same as in the first exemplary embodiment, a coil 133, a first magnet 134, a second magnet 132, third magnets 135, and a high frequency power supply 2136. The high frequency power supply 2136 supplies a high frequency AC current to the coil 133 based on a control signal inputted from the controller 2017.

The electromagnetic valve 2016 is a power valve which is inserted into the source gas supply pipe 19 and is capable of performing a switchover between an open state in which a supply of an oxygen (O₂) gas as a first source gas into the chamber 11 is allowed and a closed state in which the supply of the oxygen gas into the chamber 11 is blocked. The electromagnetic valve 2016 is equipped with a solenoid unit (not shown) having, for example, a coil, a yoke, a movable iron core and a stationary iron core; and a valve body connected to the movable iron core and configured to open or close the source gas supply pipe 19. In the electromagnetic valve 2016, if an electric current is flown to the coil of the solenoid unit, the movable iron core and the stationary iron core are magnetized, and the movable iron core is moved by an attracting force therebetween. As the movable iron core is moved, the valve body connected to the movable iron core is moved between a position where it opens the source gas supply pipe 19 and a position where it closes the source gas supply pipe 19.

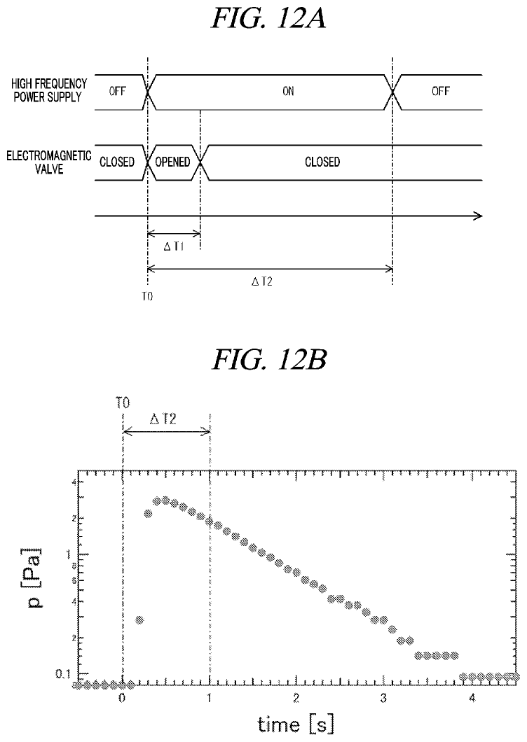

The controller 2017 controls the electromagnetic valve 2016 by controlling the electric current supplied to the solenoid unit of the electromagnetic valve 2016. Further, the controller 2017 outputs control signal to the high frequency power supply 2136 to control the supply of the AC current to the coil 133 from the high frequency power supply 2136. As shown in FIG. 12A, for example, the controller 2017 turns the electromagnetic valve 2016 into the open state and concurrently starts the supply of the AC current to the coil 133 from the high frequency power supply 2136 at a time T0. Then, upon a lapse of a preset first time (ΔT1) from the time T0, the controller 2107 turns the electromagnetic valve 2016 into the closed state. Accordingly, the source gas is instantly supplied into the chamber 11 for the first time ΔT1. Further, the first time ΔT1 is set to be, e.g., 2.6 msec. Furthermore, upon a lapse of a second time ΔT2, which is longer than the first time ΔT1, from the time T0, the controller 2017 controls the high frequency power supply 2136 to stop the supply of the AC current to the coil 133 from the high frequency power supply 2136. Here, it is desirable that the length of the second time ΔT2 is set to be equal to or larger than 10 times the length of the first time ΔT1. The second time ΔT2 is set to be, e.g., 1 sec.

Here, for the specific type ion source 2010 according to the present exemplary embodiment, a pressure variation at a downstream of the specific type ion source 2010 with a lapse of time when the source gas is supplied into the chamber 11 instantly is measured, and a measurement result will be explained. Here, the first time ΔT1 is set to be 2.6 msec; an internal pressure of the source gas supply pipe 19 during the supply of the source gas into the chamber 11 is set to be 0.5 MPa; the power to the coil 133 from the high frequency power supply 2136 is set to be 500 W; and the second time ΔT2 is set to be 1 sec. As shown in FIG. 12B, it is found out that the pressure at the downstream of the specific type ion source 2010 declines to 0.1 Pa within 4 sec from the time T0 when the electromagnetic valve 2016 is turned into the open state.

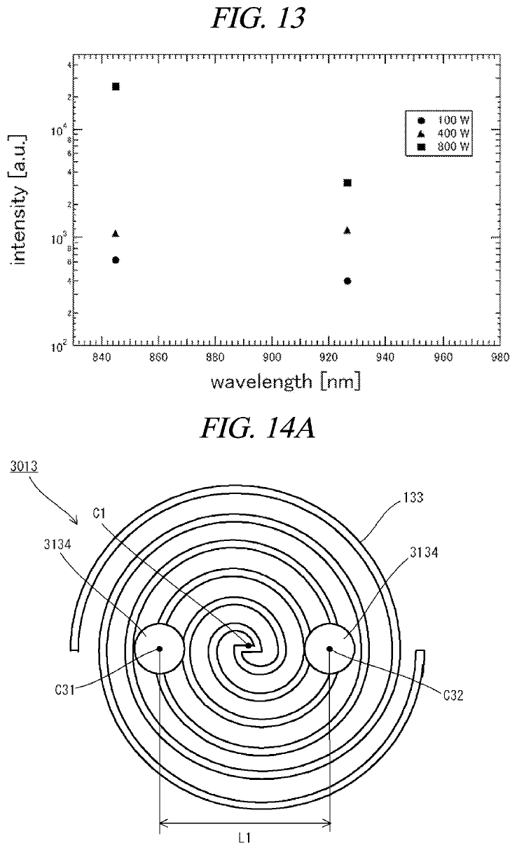

For the specific type ion source 2010 according to the present exemplary embodiment, presence or absence of O⁻ ions in plasma formed within the chamber 11 when the source gas is instantly supplied into the chamber 11 is investigated, and a result thereof will now be explained. Here, the first time ΔT1 is set to be 2.6 msec, the internal pressure of the source gas supply pipe 19 during the supply of the source gas into the chamber 11 is set to be 0.5 MPa, and the second time ΔT2 is set to be 1 sec. While varying the power to the coil 133 from the high frequency power supply 2136 to 100 W, 400 W, and 800 W, an emission spectrum of the plasma formed within the chamber 11 is measured. As illustrated in FIG. 13, this emission spectrum is found to have peaks of O atoms near 844 nm and 926 nm regardless of the power supplied to the coil 133 from the high frequency power supply 2136. As can be seen from this result, it is proved that ions of the element of the O₂ gas, which are generated as the O atoms are generated, exist in the plasma formed within the chamber 11.

As proved from these results, according to the specific type ion source 2010 of the present exemplary embodiment, it is possible to supply the O⁻ ions generated within the chamber 11 to the reactor 41 while increasing the vacuum level at the downstream of the specific type ion source 2010.

As stated above, according to the specific type ion source 2010 of the present exemplary embodiment, the controller 2017 turns the electromagnetic value 2016 into the closed state upon the lapse of the first time ΔT1 after the electromagnetic vale 2016 is turned into the open state and the supply of the AC current to the coil 133 from the high frequency power supply 2136 is concurrently begun. Accordingly, since the vacuum level of the apparatus at the downstream of the specific type ion source 2010 can be maintained high, a mean free path of the O⁻ ions is lengthened, so that the behavior of the O⁻ ions generated within the chamber 11 can be easily controlled.

Moreover, upon the lapse of the second time ΔT2 after the supply of the AC current to the coil 133 from the high frequency power supply 2136 is begun, the controller 2017 according to the present exemplary embodiment controls the high frequency power supply 2136 to block the supply of the AC current to the coil 133 from the high frequency power supply 2136. The length of the second time ΔT2 is set to be equal to or larger than 10 times the length of the first time ΔT1. Accordingly, in the second time ΔT2, a concentration of the O₂ gas is high, and the plasma is easy to form within the chamber 11. Therefore, the ions of the element of the O₂ gas included in the plasma can be supplied to the reactor 41 stably.

So far, the various exemplary embodiments of the present disclosure have been described. However, the present disclosure is not limited to the above-described exemplary embodiments. By way of example, the controller 2017 according to the present exemplary embodiments starts the supply of the AC current to the coil 133 from the high frequency power supply 2136 at the moment the electromagnetic valve 2016 is turned into the open state. However, the electromagnetic valve 2016 may be turned into the open state after the supply of the AC current to the coil 133 is begun. Further, the specific type ion source 10 may be applied to an ALD (Atomic Layer Deposition) method. In this case, DEZn is first introduced into the reactor 41, and the DEZn is self-arranged on a substrate WT. Then, a surplus of the DEZn is sent out of the reactor 41, and O⁻ ions are introduced into the reactor 41. Accordingly, the DEZn and the O⁻ ions react with each other on the substrate WT, so that ZnO is formed. Thereafter, a surplus of the O⁻ ions is sent out of the reactor 41, and DEZn is then introduced into the reactor 41 again. By repeating these series of processings afterwards, it is possible to form a thin film of the ZnO having a required film thickness.

According to the present disclosure, the substrate WT need not be exposed to the oxygen plasma when the DEZn is oxidized in the manufacturing of the thin film according to the ALD method. Therefore, a damage upon the substrate WT due to the plasma can be suppressed. Further, since the O⁻ ions are stably supplied onto a surface of the substrate WT, the ZnO thin film can be effectively buried even if a structure with a high aspect ratio and other complicated structures are formed on the substrate WT. Further, formation of a pin hole in the ZnO thin film can be suppressed. Additionally, it is possible to obtain fine ZnO particles having less defect and high activity.

The above exemplary embodiments have been described for the example where the specific type ion is the O⁻ ion. However, the specific type ion is not limited thereto. The specific type ion may be, by way of example, but not limitation, a N ion such as a N²— ion, a H ion, a C ion, or the like, and this specific type ion may be any of a cation and an anion as long as directions of an electric field and a magnetic field are reverse to each other. Further, though the exemplary embodiments have been described for the example where the second source gas is the DEZn and the ZnO is formed, the present disclosure is not limited thereto, and a cluster or a thin film of Al₂O₃, HfO₂, HfSiO, La₂O₃, SiO₂, STO, Ta₂O₅, TiO₂, or the like can be formed by changing the kind of an organic metal used as the second source gas. Alternatively, when the specific type ion is the N²— ion, a cluster or a thin film of AlN, HfN, SiN, TaN, or TiN may be formed.

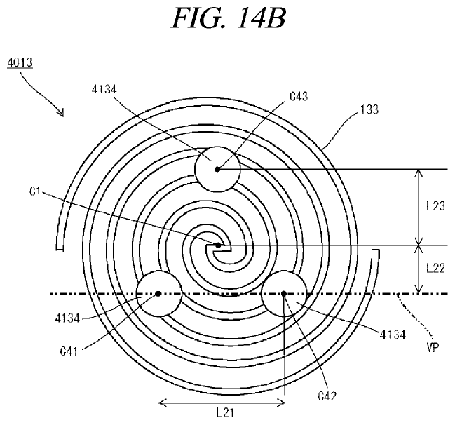

In the first exemplary embodiment, the plasma forming device 13 has the single first magnet 134 having the circular column shape. However, the number of the first magnet 134 is not limited to one. By way of example, a plasma forming device 3013 may have two first magnets 3134 having a circular column shape, which are arranged in a point symmetry with respect to a central axis C1 of a coil 133, as illustrated in FIG. 14A. Here, the first magnets 3134 are arranged such that central axes C31 and C32 thereof are substantially in parallel with the central axis C1 of the coil 133. Further, the two first magnets 3134 are arranged such that a distance L1 between their centers C31 and C32 is, e.g., 7 cm. Further, as depicted in FIG. 14B, for example, a plasma forming device 4013 may have three first magnets 4134 having a circular column shape, which are arranged to surround a central axis C1 of a coil 133. Here, the first magnets 4134 are arranged such that their central axes C41, C42 and C43 are substantially in parallel with the central axis C1 of the coil 133. Moreover, two of the three first magnets 4134 may be arranged such that a distance L21 between their centers C41 and C42 is, e.g., 6 cm, and a distance L22 between the central axis C1 of the coil 133 and a virtual plane VP including the central axes C41 and C42 is, e.g., 2 cm. In addition, the rest one of the three first magnets 4134 may be placed such that a distance L23 between a center C43 thereof and the central axis C1 of the coil 133 is, e.g., 3 cm.

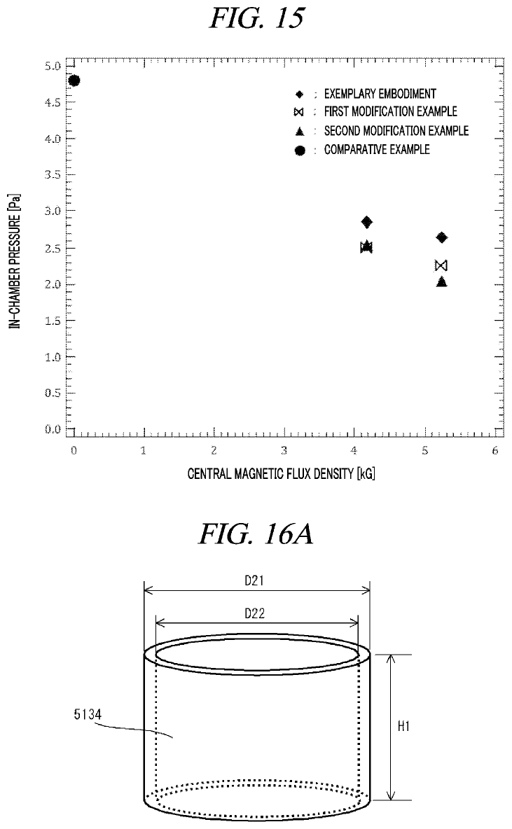

Here, for the aforementioned plasma forming device 3013 (4013), a relationship between a central magnetic flux density of the first magnet 3134 (4134) and a minimum pressure within the chamber 11 in which the source gas required for the formation of the plasma within the chamber 11 is introduced is investigated, and a result thereof will be explained here. As shown in FIG. 15, in the specific type ion source 9010 according to the aforementioned comparative example, the minimum pressure within the chamber 11 is 4.8 Pa. Meanwhile, in the plasma forming device 13 according to the present exemplary embodiment, the minimum pressure within the chamber 11 is in a range from 2.7 Pa to 2.9 Pa. In contrast, in the aforementioned plasma forming device 3013, the minimum pressure within the chamber 11 is in a range from 2.2 Pa to 2.5 Pa, and in the aforementioned plasma forming device 4013, the minimum pressure within the chamber 11 ranges from 2.0 Pa to 2.5 Pa. Further, in each of the plasma forming devices 13, 3013, and 4013 and the specific type ion source 9010, a distance between the coil 133 and the bottom wall 111a of the chamber main body 111 is set to be 8 mm. As stated above, according to the plasma forming devices 3013 and 4013, the minimum pressure within the chamber 11 can be reduced, as compared to the aforementioned comparative example or the plasma forming device 13 according to the first exemplary embodiment.

According to the present disclosure, in the plasma forming device 3013 (4013), the minimum pressure within the chamber 11 can be reduced, as compared to the aforementioned comparative example or the plasma forming device 13 of the first exemplary embodiment. Accordingly, a required amount of the source gas introduced into the chamber 11 can be reduced. Therefore, the source gas can be saved, and the ions can be supplied more stably.

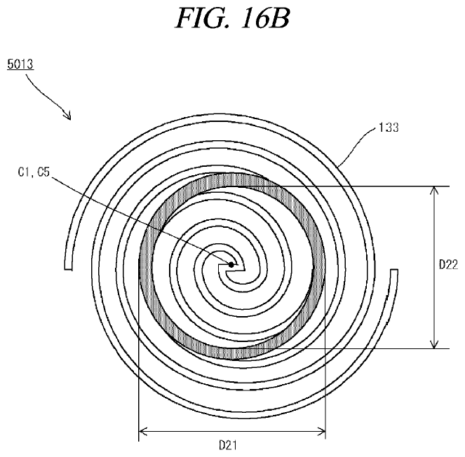

Though the above exemplary embodiments have been described for the examples where the number of the first magnet(s) 134 belonging to the plasma forming device 13 is one, two or three. However, the number of the first magnets 134 may be more than three. Further, when the multiple first magnets 134 are provided, they may be concentrically arranged around the central axis C1 of the coil 133. However, without being limited to being concentric, the first magnets 134 may be arranged in any of various layouts, surrounding the central axis C1 of the coil 133. In addition, the above exemplary embodiments have been described for the example where the first magnet 134 of the plasma forming device 13 has the circular column shape. However, the shape of the first magnet 134 is not limited to the circular column shape. By way of example, the first magnet 134 may have a cylindrical shape, the same as a first magnet 5134 shown in FIG. 16A, for example. Here, the first magnet 5134 is set to have an outer diameter D21 of, e.g., 6 cm, an inner diameter D22 of, e.g., 5 cm, and a height H1 of, e.g., 20 mm. This first magnet 5134 may be placed such that a central axis C5 thereof substantially coincides with the central axis C1 of the coil 133, the same as in a plasma forming device 5013 shown in FIG. 16B, for example. Further, the first magnet 5134 may have a rectangular parallelepiped shape or a polyprism shape.

So far, the exemplary embodiments and the modification examples (including those described in the disclosure) have been described. However, the present disclosure is not limited thereto. The various exemplary embodiments and the modification examples may be appropriately combined, or various changes and modifications may be appropriately applied thereto.

This application claims priority to Japanese Patent Application No. 2018-113593, field on Jun. 14, 2018, which application is hereby incorporated by reference in their entirety.

### INDUSTRIAL APPLICABILITY

The present disclosure is suitable for fabricating a Low-k gate oxide film, a storage capacitor dielectric, an OLED, a crystalline silicon solar cell, a passivation layer of a semiconductor device, a microwave dielectric device, a high-coatability coating film for MEMS, an oxide catalyzer layer, or the like.

### EXPLANATION OF CODES

1: Plasma film forming apparatus

10, 2010: Specific ion source

11: Chamber

12, 30: Source gas supply

13, 2013, 3013, 4013, 5013: Plasma forming device

14: Accelerator

15: Sorting device

19: Source gas supply pipe

31: Storage

33: Flow rate control valve

34: Supply pipe

35: Nozzle

41: Reactor

42: Electromagnetic field generator

43: Ar gas supply source

51: Bias application unit

111: Chamber main body

111a: Bottom wall

111b: Sidewall

112: Cover body

112a: Release hole

112b: Inlet hole

112c: Opening

132: Second magnet

133: Coil

134, 3134, 4134, 5134: First magnet

135: Third magnet

136, 2136: High frequency power supply

137: Filament

141a, 141b, 141c, 154a, 154b: Electrode

151: Main pipe

152: Branch pipe

153: Magnetic field generator

154: Accelerating/decelerating unit

155: Quadruple magnet

321, 322, 323: Heater

411: Reaction chamber

412: Trapping/growth chamber

413: Growth chamber

414: Exhaust line

2106: Electromagnetic valve

2017: Controller

A1, A2, A3: Zone

PLM: Plasma

1. A specific type ion source, comprising:
a chamber;
a first source gas supply configured to supply a first source gas into the chamber;
a plasma forming device configured to form plasma within the chamber by applying a high frequency power to the first source gas supplied into the chamber;
an accelerator configured to extract ions of an element of the first source gas included in the plasma formed within the chamber to an outside of the chamber, and configured to accelerate the extracted ions in a preset first direction; and
a sorting device configured to sort out a specific type ion from the ions accelerated by the accelerator and configured to output the sorted specific type ion in a predetermined second direction.

2. The specific type ion source of claim 1,
wherein the plasma forming device further comprises an electron supply configured to supply an electron into the chamber.

3. The specific type ion source of claim 1,
wherein the chamber comprises:
a cylindrical chamber main body; and
a cover body configured to cover an opening portion of the chamber main body, the cover body having, at a part thereof, a release hole through which an ion included in the plasma formed within the chamber main body is released to the outside of the chamber, and
wherein the plasma forming device comprises:
a coil disposed at a position outside the chamber main body, facing a bottom wall of the chamber main body, to apply the high frequency power to the first source gas within the chamber main body;
a high frequency power supply configured to supply a high frequency AC current to the coil;
a first magnet provided at an opposite side from the bottom wall of the chamber main body with respect to the coil therebetween;
a second magnet provided at an outside of the chamber main body to surround a sidewall of the chamber main body; and
a third magnet provided at a portion of the cover body to surround the release hole.

4. The specific type ion source of claim 3, further comprising:
a source gas supply pipe, communicating with an inside of the chamber, configured to supply the first source gas into the chamber;
a power valve inserted in the source gas supply pipe, and configured to perform a switchover between an open state in which a supply of the first source gas is allowed and a closed state in which the supply of the first source gas is blocked; and
a controller configured to control the power valve and the high frequency power supply,
wherein the controller is configured to control the power valve and the high frequency power supply to start a supply of the AC current to the coil from the high frequency power supply at a same time when or immediately before the controller turns the power valve into the open state, turn the power valve into the closed state upon a lapse of a preset first time after the power valve is turned into the open state, and block the supply of the AC current to the coil from the high frequency power supply upon a lapse of a preset second time, which is longer than the preset first time, after the supply of the AC current to the coil from the high frequency power supply is started.

5. The specific type ion source of claim 4,
wherein a length of the second time is equal to or larger than 10 times a length of the first time.

6. The specific type ion source of claim 3,
wherein the first magnet includes multiple first magnets.

7. The specific type ion source of claim 6,
wherein the first magnet is of a circular columnar shape, and is disposed such that a central axis of the first magnet is in parallel with a central axis of the coil.

8. The specific type ion source of claim 1,
wherein the sorting device comprises a magnetic field generator configured to generate a magnetic field of a third direction perpendicular to the first direction and the second direction.

9. The specific type ion source of claim 1,
wherein the accelerator comprises an Einzel lens configured to concentrate, by using an electromagnetic field, the ions extracted to the outside of the chamber.

10. A plasma film forming apparatus, comprising:
a specific type ion source comprising a chamber; a first source gas supply configured to supply a first source gas into the chamber; a plasma forming device configured to form plasma within the chamber by applying a high frequency power to the first source gas supplied into the chamber; an accelerator configured to extract ions of an element of the first source gas included in the plasma formed within the chamber to an outside of the chamber, and configured to accelerate the extracted ions in a preset first direction; and a sorting device configured to sort out a specific type ion from the ions accelerated by the accelerator and configured to output the sorted specific type ion in a predetermined second direction;
a second source gas supply configured to supply a second source gas; and
a reactor configured to allow the specific type ion supplied by the specific type ion source to react with the second source gas.

11. The plasma film forming apparatus of claim 10, further comprising:
an electromagnetic field generator disposed at a position at an outside of the reactor to surround a part of the reactor and configured to trap, by generating an electromagnetic field, an ion of a compound including an element corresponding to the specific type ion and an element of the second source gas into a preset zone at an inside of the reactor.

12. The plasma film forming apparatus of claim 10,
wherein the specific type ion includes an oxygen anion, a hydrogen anion, a nitrogen anion and a carbon anion.

13. The plasma film forming apparatus of claim 10,
wherein the specific type ion is only an oxygen anion.
